(19) United States
(12) Patent Application Publication
(10) Pub. No.: US 2011/0241191 A1
(43) Pub. Date: Oct. 6, 2011

(54) SEMICONDUCTOR LAMINATION PACKAGE AND METHOD OF PRODUCING SEMICONDUCTOR LAMINATION PACKAGE

(76) Inventor: Takashi KUROGI, Miyazaki (JP)

(21) Appl. No.: 13/074,286

(22) Filed: Mar. 29, 2011

(30) Foreign Application Priority Data
Mar. 30, 2010 (JP) 2010-079225

(51) Int. Cl. H01L 25/11; H01L 21/60

(52) U.S. Cl. 257/676; 438/109; 257/E25.027; 257/E21.511

(57) ABSTRACT

A semiconductor lamination package includes a first package with a first semiconductor chip mounted thereon and a second package with a second semiconductor chip mounted thereon. The first package includes first mounting pads disposed on a bottom surface thereof for transmitting an input/output signal externally from the first semiconductor IC chip. The second package is laminated on the bottom surface of the first package. The second package includes a package substrate having first bonding pads disposed on one surface thereof and second mounting pads disposed on the other surface and electrically connected to the first bonding pads; a first wiring portion for electrically connecting the first bonding pads to a chip pad of the second semiconductor chip; and a package bonding substrate having connecting pads disposed on an upper surface of the second package and a wiring path for electrically connecting the connecting pads and the chip pad.

### BACKGROUND OF THE INVENTION AND RELATED ART STATEMENT

The present invention relates to a semiconductor lamination package in which a plurality of semiconductor packages is laminated. The present invention also relates to a method of producing the semiconductor lamination package.

In a conventional semiconductor lamination package, in order to increase a density of components mounted in an electrical device, a semiconductor IC (Integrated Circuit) chip is sealed in a semiconductor package with a resin, and a plurality of semiconductor packages is laminated in a vertical direction (refer to Patent Reference).

Patent Reference: Japanese Patent Publication No. 2006-294687

According to the conventional semiconductor lamination package disclosed in Patent Reference, the semiconductor package at the upper most position and the semiconductor package at the lower most position include a plurality of mounting pads on bottom surfaces thereof, respectively, so that input/output signals are transmitted externally from the semiconductor IC chips of the semiconductor packages. The mounting pads are electrically connected to the semiconductor IC chips through a wire bonding process.

Further, the semiconductor package at the lower most position include a plurality of connecting pads on an upper surface thereof, so that the mounting pads disposed on the bottom surface of the semiconductor package at the upper most position are connected to the connecting pads through solder balls. Accordingly, the conventional semiconductor lamination package is formed of the semiconductor packages laminated in the vertical direction.

In the conventional semiconductor lamination package disclosed in Patent Reference, it is necessary to provided an additional wiring region in the semiconductor package at the lower most position on an outer circumferential side of a wiring region thereof for connecting between the semiconductor IC chip and the mounting pads, so that the connecting pads are connected to the mounting pads through the additional wiring region.

As a result, the semiconductor package at the lower most position has a forming area greater than that of the semiconductor package at the upper most position. A total forming area of the conventional semiconductor lamination package is dependent on the forming area of the semiconductor package at the lower most position.

In the conventional semiconductor lamination package disclosed in Patent Reference, accordingly, when the number of the semiconductor packages increases, the total forming area of the conventional semiconductor lamination package increases.

In view of the problems described above, an object of the present invention is to provide a semiconductor lamination package and a method of producing the semiconductor lamination package capable of solving the problems of the conventional semiconductor lamination package. In the present invention, it is possible to laminate a plurality of semiconductor packages without enlarging a total forming area of the semiconductor lamination package.

Further objects and advantages of the invention will be apparent from the following description of the invention.

### SUMMARY OF THE INVENTION

In order to attain the objects described above, according to a first aspect of the present invention, a semiconductor lamination package includes a first package with a first semiconductor chip mounted thereon and a second package with a second semiconductor chip mounted thereon. The second package is laminated on a bottom surface of the first package.

According to the first aspect of the present invention, the first package includes a plurality of first mounting pads disposed on the bottom surface thereof for transmitting an input/output signal externally from the first semiconductor IC chip.

According to the first aspect of the present invention, the second package includes a package substrate having the second semiconductor chip and a plurality of first bonding pads disposed on one surface thereof and a plurality of second mounting pads disposed on the other surface and electrically connected to the first bonding pads; a first wiring portion for electrically connecting the first bonding pads to a chip pad formed on an edge portion of an upper surface of the second semiconductor chip; and a package bonding substrate having a plurality of connecting pads disposed at positions corresponding to the first mounting pads on an upper surface of the second package and a wiring path for electrically connecting the connecting pads and the chip pad.

According to a second aspect of the present invention, a method of producing a semiconductor lamination package is applied to a semiconductor lamination package including a first package with a first semiconductor chip mounted thereon and a second package with a second semiconductor chip mounted thereon. The second package is laminated on a bottom surface of the first package.

According to the second aspect of the present invention, the method of producing the semiconductor lamination package includes the first step, the second step, the third step, the fourth step, and the fifth step.

In the first step of the method of producing the semiconductor lamination package, the second semiconductor chip is fixed to a package substrate with a plurality of first bonding pads disposed thereon. Further, the first bonding pads are electrically connected to a chip pad of the second semiconductor chip through a wire bonding.

In the second step of the method of producing the semiconductor lamination package, a package bonding substrate is fixed to an upper surface of the second semiconductor chip. The package bonding substrate includes a plurality of connecting pads disposed at a central region thereof, at least one opening portion formed between the central region and an outer circumferential region thereof, a plurality of second bonding pads disposed in a boundary region between the outer circumferential region and the opening portion, and a print wiring portion for electrically connecting the connecting pads and the second bonding pads.

In the third step of the method of producing the semiconductor lamination package, the second bonding pads are electrically connected to the chip pad through the opening portion through a wire bonding.

In the fourth step of the method of producing the semiconductor lamination package, the package substrate, the second semiconductor chip, and the package bonding substrate are sealed with a resin.

In the fifth step of the method of producing the semiconductor lamination package, a plurality of mounting pads disposed on the bottom surface of the first package is electrically and physically connected to the connecting pads.

As described above, in the present invention, the chip pad of the semiconductor chip in the lower package is connected to the mounting pads disposed on the bottom surface of the lower package through the wiring portion. Accordingly, it is possible to externally transmit the input/output signal from the semiconductor chip disposed in each of the lower package and the upper package through the wiring portion and the mounting pads of the lower package.

In the conventional semiconductor lamination package, the wiring portion is separately disposed outside the wiring portion connecting the chip pad of the semiconductor chip in the lower package to the mounting pads disposed on the bottom surface of the lower package for transmitting the input/output signal from the semiconductor chip disposed in the upper package to the mounting pads of the lower package. Accordingly, in the present invention, it is possible to reduce a total forming area of the semiconductor lamination package as opposed to the conventional semiconductor lamination package.

### BRIEF DESCRIPTION OF THE DRAWINGS

FIG. 1 is a schematic perspective view showing a semiconductor lamination package according to a first embodiment of the present invention;

FIG. 2 is a schematic sectional view showing a configuration of the semiconductor lamination package according to the first embodiment of the present invention;

FIG. 3 is a schematic plan view showing a package bonding substrate of the semiconductor lamination package according to the first embodiment of the present invention;

FIG. 4 is a schematic view No. 1 showing a lower package of the semiconductor lamination package in a manufacturing process according to the first embodiment of the present invention;

FIG. 5 is a schematic view No. 2 showing the lower package of the semiconductor lamination package in the manufacturing process according to the first embodiment of the present invention;

FIG. 6 is a schematic view No. 3 showing the lower package of the semiconductor lamination package in the manufacturing process according to the first embodiment of the present invention;

FIG. 7 is a schematic view No. 4 showing the lower package of the semiconductor lamination package in the manufacturing process according to the first embodiment of the present invention;

FIG. 8 is a schematic view No. 5 showing the lower package of the semiconductor lamination package in the manufacturing process according to the first embodiment of the present invention;

FIG. 9 is a schematic plan view showing a package bonding substrate of a semiconductor lamination package according to a second embodiment of the present invention; and

FIG. 10 is a schematic sectional view showing a semiconductor lamination package according to a third embodiment of the present invention.

### DETAILED DESCRIPTION OF PREFERRED EMBODIMENTS

Hereunder, preferred embodiments of the present invention will be explained with reference to the accompanying drawings.

According to embodiments of the present invention, a semiconductor lamination package includes a package bonding substrate fixed to an upper surface of a semiconductor IC (Integrated Circuit) chip disposed in a lower package.

In the embodiments of the present invention, the package bonding substrate has a plurality of connecting pads on an upper surface of the lower package physically, and the connecting pads are electrically connected to mounting pads disposed on a bottom surface of an upper package. Further, the package bonding substrate has a wiring path for electrically connecting the connecting pads to a chip pad of the semiconductor IC chip.

### First Embodiment

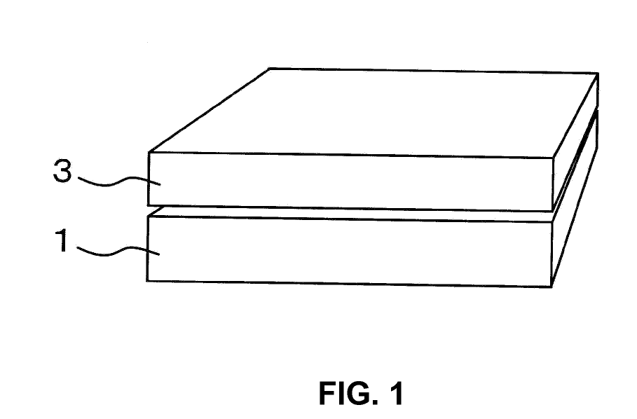

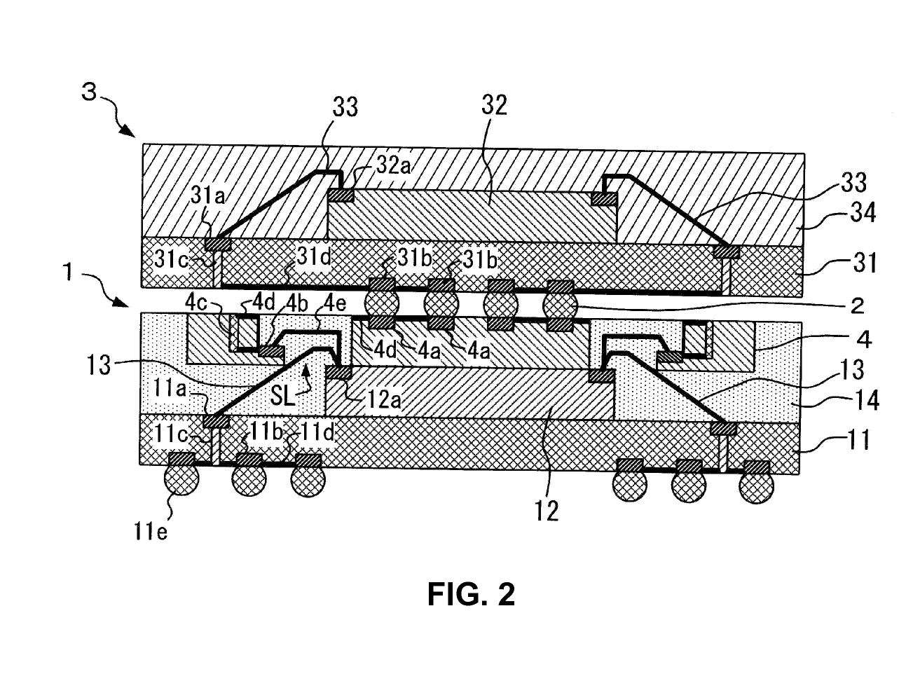

A first embodiment of the present invention will be explained. FIG. 1 is a schematic perspective view showing the semiconductor lamination package according to the first embodiment of the present invention. FIG. 2 is a schematic sectional view showing a configuration of the semiconductor lamination package according to the first embodiment of the present invention.

As shown in FIG. 1, the semiconductor lamination package includes two semiconductor packages with IC chips disposed therein, namely, a lower package 1 and an upper package 3 laminated therein.

As shown in FIG. 2, the upper package 3 includes a package substrate 31, a semiconductor IC chip 32, wiring portions 33, and a sealing member 34. The semiconductor IC chip 32 is fixed on one surface of the package substrate 31, and a plurality of bonding pads 31a is formed on the one surface of the package substrate 31. A plurality of chip pads 32a is disposed on an upper surface of the semiconductor IC chip 32 at an edge portion thereof, so that various input/output signals of the semiconductor IC chip 32 can be transmitted externally. The wiring portions 33 are provided for electrically connecting the chip pads 32a to the bonding pads 31a.

In the embodiment, the semiconductor IC chip 32 and the wiring portions 33 on the one surface of the package substrate 31 are covered with the sealing member 34. A plurality of mounting pads 31b is formed on the other surface of the package substrate 31. Further, a plurality of print wiring portions 31d is provided for electrically connecting the mounting pads 31b to the bonding pads 31a via through holes 31c formed in the package substrate 31.

In the embodiment, solder balls 2 are disposed on surfaces of the mounting pads 31b. With the solder balls 2, each of the mounting pads 31b of the upper package 3 is electrically connected to each of connecting pads 4a of the lower package 1.

As shown in FIG. 2, the lower package 1 includes a package substrate 11, a semiconductor IC chip 12, wiring portions 13, a sealing member 14, and a package bonding substrate 4. The semiconductor IC chip 12 is fixed on one surface of the package substrate 11, and a plurality of bonding pads 11a is formed on the one surface of the package substrate 11. A plurality of mounting pads 11b is formed on the other surface of the package substrate 11. Further, a plurality of print wiring portions 11d is provided for electrically connecting the mounting pads 11b to the bonding pads 11a via through holes 11c formed in the package substrate 11.

In the embodiment, solder balls 11e are formed and connected to the mounting pads 11b. A plurality of chip pads 12a is disposed on an upper surface of the semiconductor IC chip 12 at an edge portion thereof, so that various input/output signals of the semiconductor IC chip 12 can be transmitted externally. The wiring portions 13 are provided for electrically connecting the chip pads 12a to the bonding pads 11a. The package bonding substrate 4, the semiconductor IC chip 12, and the wiring portions 13 on the one surface of the package substrate 11 are covered with the sealing member 14 formed of a resin material.

In the embodiment, the package bonding substrate 4 is disposed on the upper surface of the semiconductor IC chip 12 such that one surface of the package bonding substrate 4 is exposed from the sealing member 14.

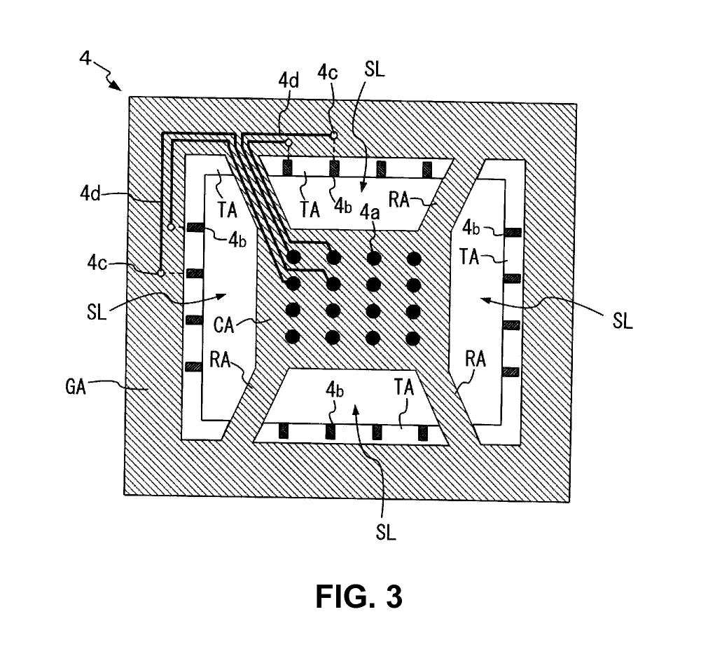

FIG. 3 is a schematic plan view showing the one surface (a front surface) of the package bonding substrate 4 of the semiconductor lamination package viewed from a side of the upper package 3 according to the first embodiment of the present invention.

As shown in FIGS. 2 and 3, the package bonding substrate 4 includes opening portions SL at four regions thereof along four sides of the semiconductor IC chip 12. The opening portions SL are provided for securing a space of bent portions of the wiring portions 13. The opening portions SL are also provided for securing a space for a wiring bonding operation for connecting bonding pads 4b and the chip pads 12a (described later). The space of the bent portions of the wiring portions 13 is filled with a resin material similar to that of the sealing member 14 as shown in FIG. 2.

As shown in FIG. 3, with the opening portions SL, the upper package 3 is divided into outer circumferential regions GA, a central region CA, and connecting regions RA connecting the outer circumferential regions GA and the central region CA. The central region CA has a shape covering the upper surface of the semiconductor IC chip 12 except the chip pads 12a disposed on the upper surface at the edge portion of the semiconductor IC chip 12.

In the embodiment, the connecting pads 4a are formed on the package bonding substrate 4 exposed from the sealing member 14 in the central region thereof. Accordingly, each of the connecting pads 4a is situated at a position corresponding to each of the mounting pads 31b of the upper package 3. A step portion TA is formed in a boundary between the outer circumferential region GA and the opening portion SL at a position lower than the front surface of the package bonding substrate 4. A plurality of bonding pads 4b is formed on a surface of the step portion TA. A plurality of print wiring portion 4d is formed on surfaces of the outer circumferential regions GA and the connecting regions RA for electrically connecting the connecting pads 4a to the bonding pads 4b via through holes 4c formed in the outer circumferential regions GA.

In the embodiment, the bonding pads 4b are formed on the step portions TA of the package bonding substrate 4. Wiring portions 4e are provided for electrically connecting the bonding pads 4b to the chip pads 12a of the semiconductor IC chip 12.

In the embodiment, with the configuration of the semiconductor lamination package described above, the mounting pads 31b of the upper package 3 are electrically connected to the mounting pads 11b of the lower package 1 through the solder balls 2, the connecting pads 4a, the print wiring portion 4d, the through holes 4c, the bonding pads 4b, the wiring portions 4e, the wiring portions 13, the bonding pads 11a, the through holes 11c, and the print wiring portions 11d.

Accordingly, an output signal is output externally from an integrated circuit of the semiconductor IC chip 32 of the upper package 3 through the mounting pads 31b of the upper package 3, the package bonding substrate 4 of the lower package 1 and the wiring portions 13. Further, an output signal is output externally from an integrated circuit of the semiconductor IC chip 12 of the lower package 1 through the wiring portions 13 and the mounting pads 11b of the lower package 1.

Further, an input signal is input externally from the mounting pads 11b of the lower package 1 to an integrated circuit of the semiconductor IC chip 12 of the lower package 1 through the wiring portions 13. Further, an input signal is input externally from the mounting pads 11b of the lower package 1 to an integrated circuit of the semiconductor IC chip 32 of the upper package 3 through the wiring portions 13, the package bonding substrate 4, the solder balls 2, and the mounting pads 31b of the upper package 3.

As described above, in the semiconductor lamination package shown in FIG. 2, it is configured such that the various input/output signals are transmitted externally from the integrated circuit of the semiconductor IC chip 32 of the upper package 3 through the mounting pads 31b disposed in the central region of the bottom surface of the upper package 3. Further, in the lower package 1, the connecting pads 4a disposed in the central region of the package bonding substrate 4 are physically and electrically connected to the mounting pads 31b.

Further, in the package bonding substrate 4, as shown in FIG. 3, the input/output signals transmitted to the connecting pads 4a are further transmitted to the outer circumferential regions GA. Further, the wiring portions 4e are provided for electrically connecting the bonding pads 4b disposed on the step portions TA of the outer circumferential regions GA to the chip pads 12a of the semiconductor IC chip 12. Accordingly, the input/output signals transmitted from the semiconductor IC chip 32 of the upper package 3 are transmitted from the mounting pads 11b disposed on the bottom surface of the lower package 1 through the wiring portions 13, similar to the input/output signals transmitted from the semiconductor IC chip 12 of the lower package 1.

In a conventional semiconductor lamination package, it is necessary to provide an additional wiring portion in an outer side of a wiring portion for externally transmitting an output/input signal from a semiconductor IC chip of a lower package, so that an output/input signal is externally transmitted from a semiconductor IC chip of an upper package.

As opposed to the conventional semiconductor lamination package, in the embodiment, with the configuration described above, it is possible to reduce a total forming area of an entire portion of the semiconductor lamination package.

In the embodiment, as shown in FIG. 2, the mounting pads 11b are disposed only in the outer circumferential region of the bottom surface of the lower package 1, that is, the regions except the central region just below the semiconductor IC chip 12. Even in this configuration, it is still possible to reduce the total forming area of the entire portion of the semiconductor lamination package, as opposed to the conventional semiconductor lamination package.

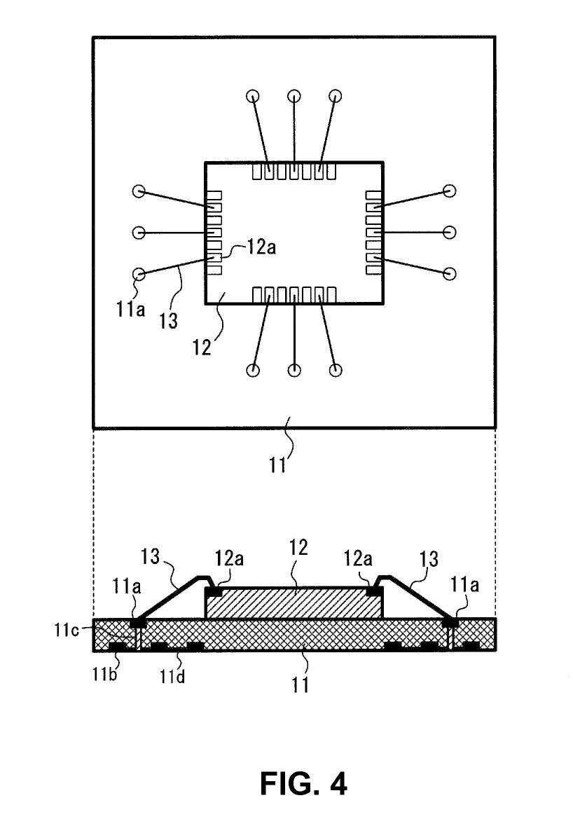

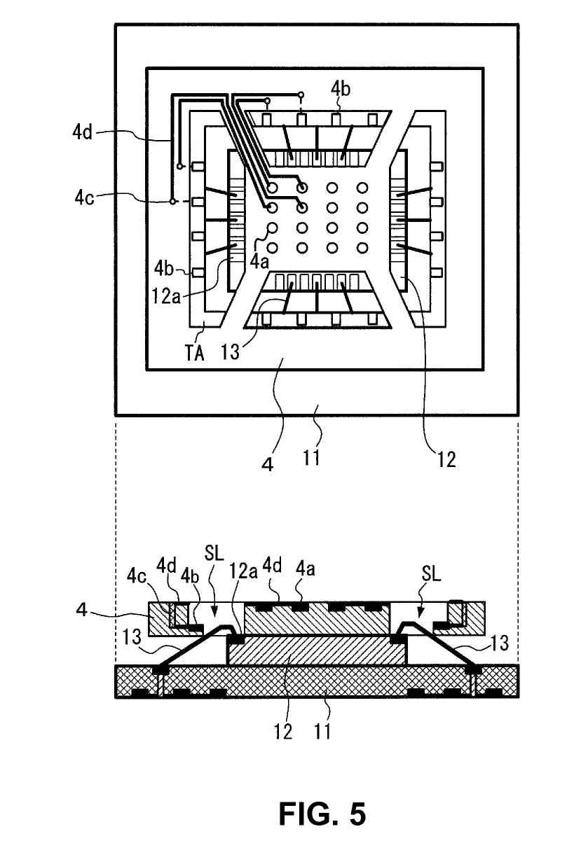

A method of producing the lower package 1 shown in FIG. 2 will be explained next with reference to FIGS. 4 to 8. FIG. 4 is a schematic view No. 1 showing the lower package 1 of the semiconductor lamination package in a manufacturing process according to the first embodiment of the present invention. FIG. 5 is a schematic view No. 2 showing the lower package 1 of the semiconductor lamination package in the manufacturing process according to the first embodiment of the present invention.

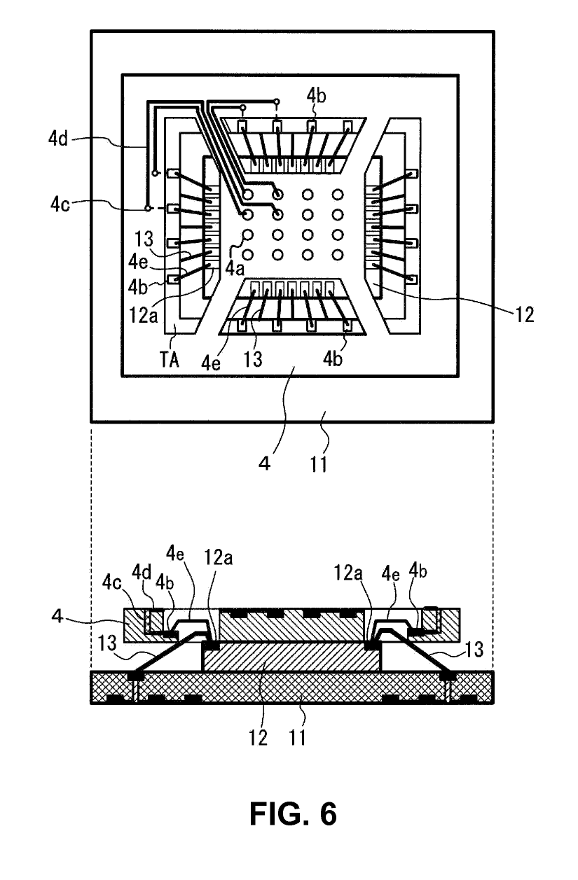

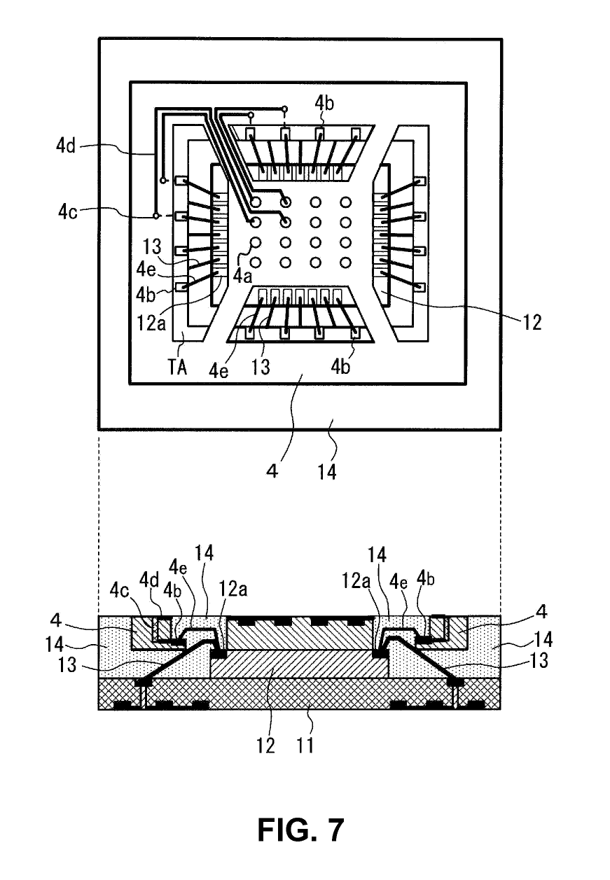

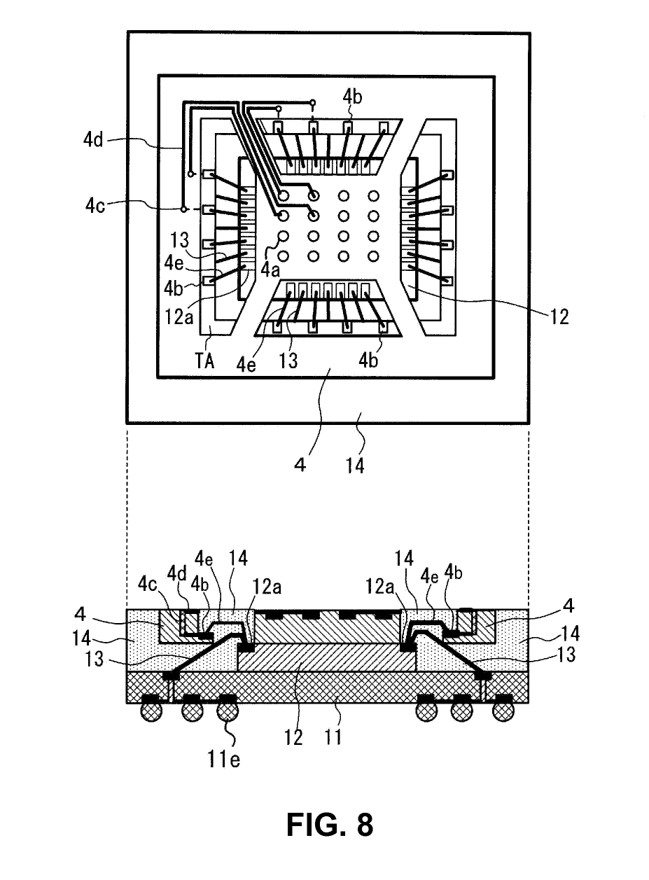

FIG. 6 is a schematic view No. 3 showing the lower package 1 of the semiconductor lamination package in the manufacturing process according to the first embodiment of the present invention. FIG. 7 is a schematic view No. 4 showing the lower package 1 of the semiconductor lamination package in the manufacturing process according to the first embodiment of the present invention. FIG. 8 is a schematic view No. 5 showing the lower package 1 of the semiconductor lamination package in the manufacturing process according to the first embodiment of the present invention.

As shown in FIG. 4, first, in the first step, the semiconductor IC chip 12 is fixed to the one surface of the package substrate 11 through a die bonding process. It is noted that the bonding pads 11a are formed on the one surface of the package substrate 11, and the mounting pads 11b, the through holes 11c, and the print wiring portions 11d are formed on the other surface of the package substrate 11.

In the next step, the wiring portions 13 are formed to connect the chip pads 12a disposed on the upper surface of the semiconductor IC chip 12 at the edge portion thereof to the bonding pads 11a through a wire bonding process.

As shown in FIG. 5, in the next step as the second step, the package bonding substrate 4 having the configuration shown in FIGS. 2 and 3 is fixed to the upper surface of the semiconductor IC chip 12. At this moment, as shown in FIG. 5, the chip pads 12a of the semiconductor IC chip 12 are exposed through the opening portions SL of the package bonding substrate 4 in a plan view from above in the state that the package bonding substrate 4 is fixed to the semiconductor IC chip 12. Further, the bent portions of the wiring portions 13 for connecting the chip pads 12a and the bonding pads 11a are exposed in the spaces created with the opening portions SL.

As shown in FIG. 6, in the next step as the third step, the wiring portions 4e are formed through the wire bonding process, so that the bonding pads 4b disposed on the step portions TA of the package bonding substrate 4 are connected to the chip pads 12a of the semiconductor IC chip 12.

As shown in FIG. 7, in the next step as the fourth step, a resin material such as an epoxy resin is applied to seal the semiconductor IC chip 12, the one surface of the package substrate 11, and the package bonding substrate 4. Accordingly, a sealed member 14 is formed.

As shown in FIG. 8, in the next step as the fifth step, the solder balls 11e are disposed on the mounting pads 11b of the package substrate 11. In the next step, the solder balls 2 are formed so that the connecting pads 4a disposed on the upper surface of the lower package 1 are connected to the mounting pads 31b disposed on the bottom surface of the upper package 3 through the solder balls 2, thereby completing the semiconductor lamination package.

### Second Embodiment

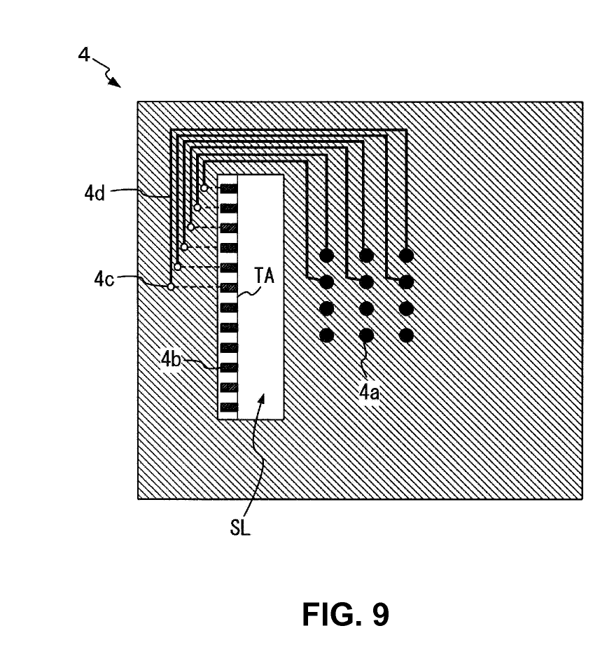

A second embodiment of the present invention will be explained next. FIG. 9 is a schematic plan view showing the package bonding substrate 4 of the semiconductor lamination package according to the second embodiment of the present invention.

In the first embodiment, the opening portions Sl are formed separately at the four locations as shown in FIG. 3. Accordingly, it is possible to secure the space for the wire bonding process to connect between the chip pads 12a of the semiconductor IC chip 12 and the bonding pads 4b. Alternatively, as shown in FIG. 9, the opening portion SL may be formed at one location.

### Third Embodiment

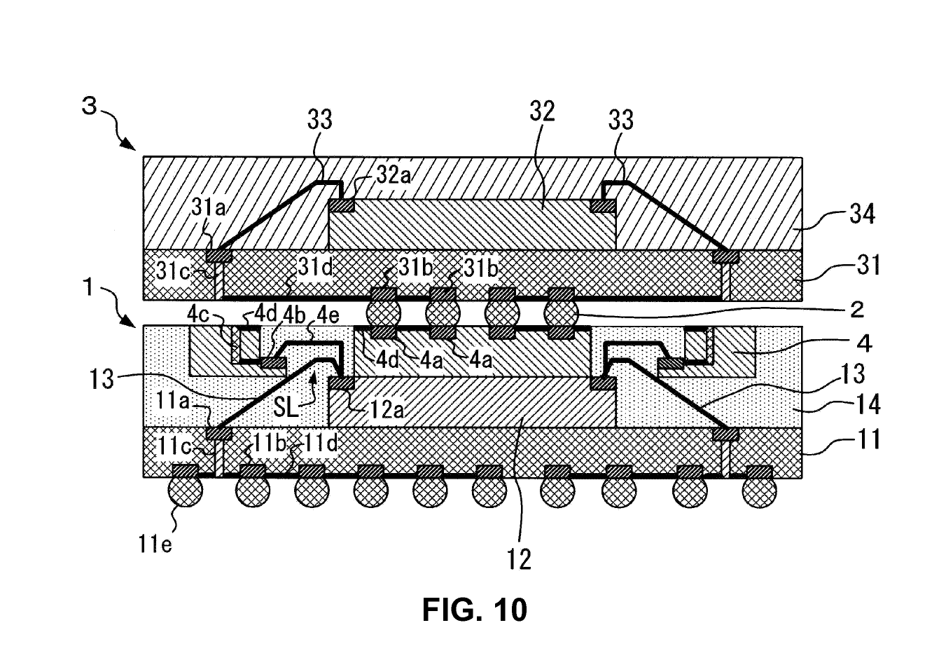

A third embodiment of the present invention will be explained next. FIG. 10 is a schematic sectional view showing the semiconductor lamination package according to the third embodiment of the present invention.

In the first embodiment, in the package substrate 11 of the lower package 1, the mounting pads 11b are disposed only in the outer circumferential regions of the bottom surface except the central region (the region just below the region where the semiconductor IC chip 12 is fixed). Alternatively, as shown in FIG. 10, the mounting pads 11b may be formed in the central region.

The disclosure of Japanese Patent Application No. 2010-079255, filed on Mar. 30, 2010, is incorporated in the application by reference.

While the invention has been explained with reference to the specific embodiments of the invention, the explanation is illustrative and the invention is limited only by the appended claims.

What is claimed is:

1. A semiconductor lamination package, comprising:
a first package with a first semiconductor chip mounted thereon, said first package including a plurality of first mounting pads disposed on a bottom surface thereof for transmitting an input/output signal externally from the first semiconductor IC chip; and
a second package with a second semiconductor chip mounted thereon, said second package being laminated on the bottom surface of the first package,
wherein said second package includes a package substrate having a plurality of first bonding pads disposed on one surface thereof and a plurality of second mounting pads disposed on the other surface and electrically connected to the first bonding pads; a first wiring portion for electrically connecting the first bonding pads to a chip pad of the second semiconductor chip; and a package bonding substrate having a plurality of connecting pads disposed on an upper surface of the second package and a wiring path for electrically connecting the connecting pads to the chip pad.

2. The semiconductor lamination package according to claim 1, wherein said chip pad is formed on an edge portion of an upper surface of the second semiconductor chip.

3. The semiconductor lamination package according to claim 1, wherein said connecting pads are disposed at positions corresponding to the first mounting pads.

4. The semiconductor lamination package according to claim 1, wherein said package bonding substrate is fixed to the upper surface of the second semiconductor chip so that an upper surface of the package bonding substrate is flush with the upper surface of the second package.

5. The semiconductor lamination package according to claim 1, wherein said package bonding substrate further includes an opening portion for exposing the chip pad and a plurality of second bonding pads, said opening portion being formed between a central region and an outer circumferential region of the package bonding substrate, said second bonding pads being arranged between the opening portion and the outer circumferential region.

6. The semiconductor lamination package according to claim 5, wherein said wiring path includes a print wiring portion for electrically connecting the connecting pads and the second bonding pads, and a second wiring portion for electrically connecting the second bonding pads to the chip pad in the opening portion.

7. The semiconductor lamination package according to claim 5, wherein said second bonding pads are situated below an upper surface of package bonding substrate so that a bent portion of the first wiring portion and the second wiring portion are situated in the opening portion.

8. A method of producing a semiconductor lamination package including a first package with a first semiconductor chip mounted thereon and a second package with a second semiconductor chip mounted thereon, said second package being laminated on a bottom surface of the first package, comprising the steps of:
fixing the second semiconductor chip to a package substrate with a plurality of first bonding pads disposed thereon;
electrically connecting the first bonding pads to a chip pad of the second semiconductor chip through a wire bonding process;
fixing a package bonding substrate to an upper surface of the second semiconductor chip, said package bonding substrate including a plurality of connecting pads disposed at a central region thereof, at least one opening portion formed between the central region and an outer circumferential region thereof, a plurality of second bonding pads disposed in a boundary region between the outer circumferential region and the opening portion, and a print wiring portion for electrically connecting the connecting pads and the second bonding pads;
electrically connecting the second bonding pads to the chip pad through the opening portion through a wire bonding process;
sealing the package substrate, the second semiconductor chip, and the package bonding substrate with a resin; and
electrically and physically connecting a plurality of mounting pads disposed on the bottom surface of the first package to the connecting pads.
